(19) United States
(12) Patent Application Publication
(10) Pub. No.: US 2025/0266225 A1
(43) Pub. Date: Aug. 21, 2025

(54) SWITCH DEVICE

(71) Applicant: ADVANTEST CORPORATION, Tokyo (JP)

(72) Inventors: Taku SATO, Tokyo (JP); Koji YAMASHITA, Tokyo (JP)

(21) Appl. No.: 18/939,391

(22) Filed: Nov. 6, 2024

(30) Foreign Application Priority Data
Feb. 16, 2024 (JP) 2024-022448

(51) Int. Cl. H01H 37/72

(52) U.S. Cl. CPC H01H 37/72

(57) ABSTRACT

Provided is a switch device including a phase-change material switch and a first series switch which is connected in series to the phase-change material switch and is normally on. In the phase-change material switch and the first series switch, between a first terminal and a second terminal of the switch device, the phase-change material switch may be connected to a side of the first terminal, and the first series switch may be connected to a side of the second terminal, and a control terminal of the first series switch may be connected to a terminal of the phase-change material switch on a side of the first terminal.

The contents of the following patent application(s) are incorporated herein by reference: NO. 2024-022448 filed in JP on Feb. 16, 2024

### BACKGROUND

### 1. Technical Field

The present invention relates to a switch device.

### 2. Related Art

Patent Document 1 describes that “FIG. 2 is a circuit diagram illustrating a configuration of a memory cell MM included in a memory array 1. In FIG. 2, the memory cell MM includes an N-channel MOS transistor 4 and a phase-change element 5. In the N-channel MOS transistor 4, a gate G receives a word line voltage VWL, a source S receives a source line voltage VSL, a substrate SUB (well, back gate) receives a well line voltage VMW, and a drain D is connected to one electrode of the phase-change element 5. Another electrode of the phase-change element 5 receives a bit line voltage VBL. The word line voltage VWL and the bit line voltage VBL are controlled by a write circuit 2 and a read circuit 3. Both the source line voltage VSL and the well voltage VMW are fixed to a ground voltage (0 V).” (paragraph 0010).

Patent Document 2 describes that “FIG. 1 shows a schematic configuration of a phase-change memory 7. A memory array (MARY) 10 is constituted by word lines WL0 to WLn, bit lines BL0 to BLk, and a plurality of memory cells 11 (M00 to Mnk) arranged at intersections of the word lines and the bit lines. Although various configurations of the memory cell 11 will be described in detail later, here, as an example, a configuration using a selection transistor CT as a selection element and a storage element PCR as a phase-change element using a phase-change material will be described. The memory cell 11 is constituted by connecting the selection transistor CT and the storage element PCR in series in a direction from the bit line to a feeder line of a ground voltage Vss.” (paragraph 0049).

Patent Document 3 describes that “A phase-change memory cell 104a includes a phase-change element 106a and a TFET 108a. One end of the phase-change element 106a is electrically coupled to a bit line 112a, and another end of the phase-change element 106a is electrically coupled to the drain of the TFET 108a. The source of the TFET 108a is electrically coupled to a ground plate 114. The gate of the TFET 108a is electrically coupled to a word line 110a. A phase-change memory cell 104b includes a phase-change element 106b and a TFET 108b. One end of the phase-change element 106b is electrically coupled to the bit line 112a, and another end of the phase-change element 106b is electrically coupled to the drain of the TFET 108b. The source of the TFET 108b is electrically coupled to the ground plate 114.” (paragraph 0017).

Patent Document 4 describes that “A schematic diagram of a memory system 100 according to an embodiment of the present invention is shown with reference to FIG. 1. The memory system 100 includes memory cells 102 in an array configuration. Each of the memory cells 102 includes a switch element 104, such as, for example, a metal-insulator-metal (MIM) switch cell or a phase-change switch cell, and a cell transistor 106, such as, for example, a junction field effect transistor (JFET).” (paragraph 0019), and “The switch element 104 includes a first side 114and a second side 116. The first side 114 is connected to one of the word lines 118, such as a word line 1 through a word line 1024, of the memory system 100, for example. The second side 116 is connected to the gate terminal 108 of the cell transistor 106.” (paragraph 0021).

### PRIOR ART DOCUMENTS

### Patent Document

Patent Document 1: Japanese Patent Application Publication No. 2009-252253

Patent Document 2: International Publication No. 2010/004652

Patent Document 3: Japanese Patent Application Publication No. 2008-021970

Patent Document 4: Japanese translation publication of a PCT rout patent application No. 2009-538491

### Non-Patent Document

Non-Patent Document 1: Tejinder Singh et al., “Reconfigurable PCM GeTe-based Latching 6-bit Digital Switched Capacitor Bank”, 15th European Microwave Integrated Circuits Conference (EuMIC), Utrecht, Netherlands, pp. 93-96, January 2021

Non-Patent Document 2: Tejinder Singh et al., “Ultra-Compact Phase-Change GeTe-Based Scalable mmWave Latching Crossbar Switch Matrices”, IEEE Transactions on Microwave Theory and Techniques, pp. 938-949, December 2021

### BRIEF DESCRIPTION OF THE DRAWINGS

FIG. 1 shows a configuration of a switch device 10 according to the present embodiment.

FIG. 2 shows a configuration of a switch device 20 according to a modification of the present embodiment.

FIG. 3 shows a configuration of a capacitor bank 30 according to the present embodiment.

FIG. 4 shows a configuration of a switch matrix 40 according to the present embodiment.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

A phase-change material (PCM) is a material capable of reversibly changing the phase between an amorphous phase having a high resistance and a low refractive index and a crystalline phase having a low resistance and a high refractive index through a heating and cooling cycle. Such a phase-change material is, for example, GeTe (germanium telluride) or Sb₂Te₃ (antimony telluride). In a switch using the phase-change material (also referred to as “phase-change material switch” and “PCM-SW”), the phase-change material is disposed between terminals, and the phase-change material can be switched between a high resistance state (off state) and a low resistance state (on state) by a heating/cooling cycle. The phase-change material switch is a non-volatile operating device and does not require power supply to maintain the on state and the off state.

Such a phase-change material switch is applied to a nonvolatile phase-change memory (see Patent Documents 1 to 4), a switched capacitor bank (see Non-Patent Document 1), a switch matrix (see Non-Patent Document 2), and the like. However, the phase-change material switch has a low withstand voltage between terminals of about 4 V as an example, and is difficult to be applied to applications requiring a high withstand voltage. In the present embodiment, it is possible to realize a switch device having a higher withstand voltage than a phase-change material switch alone by using the phase-change material switch.

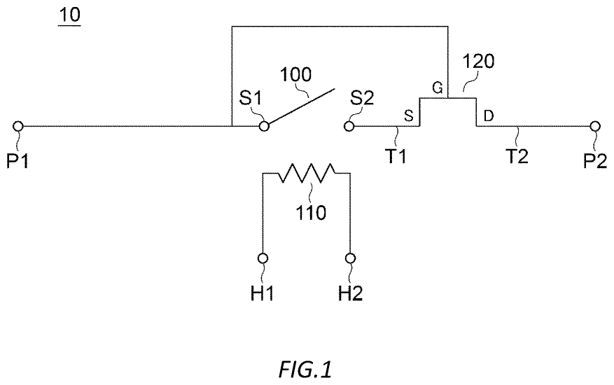

FIG. 1 shows a configuration of a switch device 10 according to the present embodiment. The switch device 10 functions as a non-volatile switch that electrically connects or disconnects a first terminal P1 and a second terminal P2. The switch device 10 includes a phase-change material switch 100, a heater 110, and a series switch 120. The phase-change material switch 100 has a structure in which a channel of a phase-change material is disposed between terminals S1 and S2. Here, the “channel” means a member that switches on and off (whether to allow or block current flow) between the terminals S1 and S2.

The heater 110 is disposed near the channel of the phase-change material switch 100 and heats the phase-change material switch 100 when the phase-change material switch 100 is switched to be turned on or off. In the present embodiment, the heater 110 is formed of an electrothermal material such as tungsten. The heater 110 generates greater heat as the current flowing between terminals H1 and H2 increases.

The heater 110 changes the phase-change material from the crystalline phase to the amorphous phase by heating the phase-change material of the phase-change material switch 100 to a high temperature (in the case of a GeTe film, 700° C. as an example) equal to or higher than the melting point, and then stopping heating and quenching it. The heater 110 changes the phase-change material from the amorphous phase to the crystalline phase by thermally annealing the phase-change material of the phase-change material switch 100 at a relatively low temperature (in the case of a GeTe film, 200° C. as an example) equal to or higher than a crystallization temperature. A control device that controls the switching of the switch device 10 may change the phase state of the phase-change material as described above by controlling the current flowing between the terminals H1 and H2 of the heater 110. Note that in the present embodiment, a configuration using an electric heater as the heater 110 is exemplified, but the heater 110 may heat the phase-change material switch 100 by another method such as light irradiation.

The series switch 120 is connected in series to the phase-change material switch 100. The series switch 120 is a semiconductor switch element such as a metal oxide semiconductor field effect transistor (MOSFET) or an insulated gate bipolar transistor (IGBT). The series switch 120 may be a GaN-FET, a Si-MOSFET, a SiC-MOSFET, a SiC-IGBT, or the like. The series switch 120 includes a first main terminal, a second main terminal, and a control terminal that controls a connection state between the first main terminal and the second main terminal. When the series switch 120 is a MOSFET, a GaN FET, or the like, the series switch 120 has a drain and a source as the first main terminal and the second main terminal, and has a gate as the control terminal. When the series switch 120 is an IGBT, the series switch 120 has a collector and an emitter as the first main terminal and the second main terminal, and has a gate as the control terminal. In the present embodiment, for convenience of description, a case will be described in which the series switch 120 is a GaN-FET.

The series switch 120 is a normally-on switch. In the present embodiment, in the phase-change material switch 100 and the series switch 120, between the first terminal P1 and the second terminal P2 of the switch device 10, the phase-change material switch 100 is connected to the first terminal P1 side, and the first series switch 120 is connected to the second terminal P2 side. In the example of this drawing, the terminal S1 of the phase-change material switch 100 is directly connected to the first terminal P1, a first main terminal T1 (a source as an example) of the series switch 120 is directly connected to the terminal S2 of the phase-change material switch 100, and a second main terminal T2 (a drain as an example) of the series switch 120 is directly connected to the second terminal P2. Alternatively, a passive component such as a resistor or an inductor may be provided in at least one of the following: between the first terminal P1 and the terminal S1, between the terminal S2 and the first main terminal T1, or between the second main terminal T2 and the second main terminal P2.

A control terminal G of the series switch 120 is connected to the terminal S1 of the phase-change material switch 100 on the first terminal P1 side. In the example of this drawing, the control terminal G of the series switch 120 is directly connected to the terminal S1 of the phase-change material switch 100. Alternatively, a passive component such as a resistor or an inductor may be provided between the terminal S1 and the control terminal G of the series switch 120.

In the present embodiment, the series switch 120 may be designed to be turned off in response to the potential difference of the second terminal P2 from the first terminal P1 exceeding a first threshold. In this drawing, the series switch 120 is turned off when a potential difference between the control terminal G and the first main terminal T1, more specifically, a gate-source voltage (=the voltage of the control terminal G-the voltage of the first main terminal T1) is equal to or lower than a threshold voltage TH of the series switch 120, and is turned on when the potential difference exceeds the threshold voltage TH. Since the series switch 120 is normally on, the threshold voltage TH is lower than 0.

As an example, in a case where the first terminal P1 is 0 V, the threshold voltage TH of the series switch 120 is −2 V, and the withstand voltage of the phase-change material switch 100 is 4 V, the operation of the switch device 10 when the voltage of the second terminal P2 rises from 0 V to 4 V or more after the phase-change material switch 100 is turned off will be described. When the phase-change material switch 100 is in the on state, both the control terminal G and the first main terminal T1 of the series switch 120 are 0 V, and thus the gate-source voltage of the series switch 120 is 0 V, which is higher than the threshold voltage TH (−2 V), so that the series switch 120 is turned on. When the phase-change material switch 100 is turned off in this state, the series switch 120 maintains the on state.

When the voltage of the second terminal P2 rises to near 2 V, the series switch 120 is turned on, so that the terminal T1 rises to near 2 V. When the voltage at the second terminal P2 reaches 2 V, the control terminal of the series switch 120 is at 0 V, the terminal T1 is at 2 V, and the gate-source voltage of the series switch 120 is at −2 V, which is equal to or lower than the threshold voltage TH (−2 V), so that the series switch 120 is turned off. Thereafter, even when the voltage at the second terminal P2 further rises to 4 V or more, the voltage at the terminal T1 does not rise beyond 2 V since the series switch 120 is turned off. Therefore, the switch device 10 can limit the voltage applied to the phase-change material switch 100 to lower than the absolute value (2 V in this example) of the threshold voltage TH of the series switch 120.

In this way, by setting the threshold voltage of the series switch 120 to −2 V, it is possible to make the series switch 120 turn off in response to the potential difference of the second terminal from the first terminal P1 exceeding the first threshold of 2 V. Then, the switch device 10 is designed such that the first threshold is lower than the withstand voltage of the phase-change material switch 100, whereby a switch having a high withstand voltage can be realized by using the phase-change material switch 100. Note that in order to provide a sufficient margin for the withstand voltage, the first threshold may be ½ or less, ⅓ or less, ¼ or less, or the like of the withstand voltage of the phase-change material switch 100.

Note that the withstand voltage of the series switch 120 may be higher than the withstand voltage of the phase-change material switch 100. Accordingly, a withstand voltage exceeding twice the withstand voltage of the phase-change material switch 100 can be realized as the entire switch device 10. The series switch 120 may be a high withstand voltage switch having a sufficiently high withstand voltage as compared to the phase-change material switch 100. The withstand voltage of the series switch 120 may be, for example, 5 times or higher, 10 times or higher, 20 times or higher, 50 times or higher, or 100 times or higher the withstand voltage of the phase-change material switch 100.

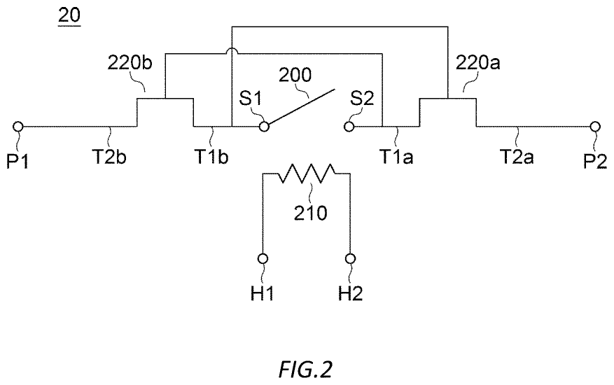

FIG. 2 shows a configuration of a switch device 20 according to a modification of the present embodiment. The switch device 20 shown in this drawing is a modification of the switch device 10 shown in FIG. 1, and thus the description thereof will be omitted except for the following difference.

The switch device 20 has a function of protecting a phase-change material switch 200 from overvoltage not only when the potential of the second terminal P2 is relatively higher than the potential of the first terminal P1 but also when the potential of the second terminal P2 is relatively lower than the potential of the first terminal P1. The switch device 20 includes a phase-change material switch 200, a heater 210, and series switches 220a to 220b.

The phase-change material switch 200 may have a function and a configuration similar to those of the phase-change material switch 100 shown in FIG. 1. The heater 210 may have a function and a configuration similar to those of the heater 110 shown in FIG. 1. The series switch 220a and the series switch 220b are normally-on switches. The series switch 220a and the series switch 220b are connected in series to the phase-change material switch 100 between the first terminal P1 and the second terminal P2 of the switch device 20. The series switch 220a is an example of the “first series switch”, and is connected on the second terminal P2 side with respect to the phase-change material switch 200 between the first terminal P1 and the second terminal P2 of the switch device 20. In the example of this drawing, a first main terminal T1a (a source as an example) of the series switch 220a is directly connected to the terminal S2 of the phase-change material switch 200, and a second main terminal T2a (a drain as an example) of the series switch 220a is directly connected to the second terminal P2. Instead of directly connecting these terminals, a passive component may be provided between the terminals.

The control terminal G of the series switch 220a is connected to the terminal S1 of the phase-change material switch 200 on the first terminal P1 side. In the example of this drawing, the control terminal G of the series switch 220a is directly connected to the terminal S1 of the phase-change material switch 200. The control terminal G of the series switch 220a may be directly connected to the first terminal P1. A passive component such as a resistor or an inductor may be provided between the terminal S1 or the first terminal P1 and the control terminal G of the series switch 220a.

The series switch 220b is an example of the “second series switch”, and is connected on the first terminal P1 side with respect to the phase-change material switch 200 between the first terminal and the second terminal of the switch device 20. In the example of this drawing, a first main terminal T1b (a source as an example) of the series switch 220b is directly connected to the terminal S2 of the phase-change material switch 200, and a second main terminal T2b (a drain as an example) of the series switch 220b is directly connected to the first terminal P1. Instead of directly connecting these terminals, a passive component may be provided between the terminals.

The control terminal G of the series switch 220b is connected to the terminal S2 of the phase-change material switch 200 on the second terminal P2 side. In the example of this drawing, the control terminal G of the series switch 220b is directly connected to the terminal S2 of the phase-change material switch 200. The control terminal G of the series switch 220b may be directly connected to the second terminal P2. A passive component such as a resistor or an inductor may be provided between the terminal S2 or the second terminal P2 and the control terminal G of the series switch 220b.

The series switch 220a and the series switch 220b may have functions and configurations similar to those of the series switch 120 shown in FIG. 1 except for the following points. Here, the series switch 220b may be designed to be turned off in response to the potential difference of the second terminal P2 from the first terminal P1 exceeding the first threshold similarly to the series switch 120 and the series switch 220a. Alternatively, the series switch 220b may be designed to be turned off in response to the potential difference of the second terminal P2 from the first terminal P1 exceeding a second threshold different from the first threshold. The second threshold may be determined so as to satisfy a constraint similar to the first threshold described with reference to FIG. 1.

The operation of the switch device 20 shown in FIG. 2 can be described as follows based on the operation of the switch device 10 shown in FIG. 1.

### (1) When the Potential of the Second Terminal P2 is Higher Than the Potential of the First Terminal P1

The control terminal G of the series switch 220b is connected to the second terminal P2 via the series switch 220a. Therefore, when the voltage of the first terminal P1 is equal to or lower than the voltage of the second terminal P2, the voltage of the control terminal G of the series switch 220b becomes equal to or higher than the voltage of the first main terminal T1b of the series switch 220b. Thus, the gate-source voltage of the series switch 220b becomes higher than the threshold voltage TH (a negative value such as −2 V), so that the series switch 220b is turned on.

Therefore, when the potential of the second terminal P2 is higher than the potential of the first terminal P1, the switch device 20 can be regarded as a circuit equivalent to the switch device 10, and similarly to the switch device 10, the voltage applied to the phase-change material switch 200 can be limited to lower than the absolute value of the threshold voltage TH of the series switch 220a.

### (2) When the Potential of the First Terminal P1 is Higher Than the Potential of the Second Terminal P2

The control terminal G of the series switch 220a is connected to the first terminal P1 via the series switch 220b. Therefore, when the voltage of the second terminal P2 is equal to or lower than the voltage of the first terminal P1, the voltage of the control terminal G of the series switch 220a becomes equal to or higher than the voltage of the first main terminal T1a of the series switch 220a. Thus, the gate-source voltage of the series switch 220a becomes higher than the threshold voltage TH (a negative value such as −2 V), so that the series switch 220a is turned on.

Therefore, when the potential of the first terminal P1 is higher than the potential of the second terminal P2, the switch device 20 can be regarded as a circuit equivalent to a circuit in which the first terminal P1 and the second terminal P2 in the switch device 10 shown in FIG. 1 are reversed, and similarly to the switch device 10, the voltage applied to the phase-change material switch 200 can be limited to lower than the absolute value of the threshold voltage TH of the series switch 220b.

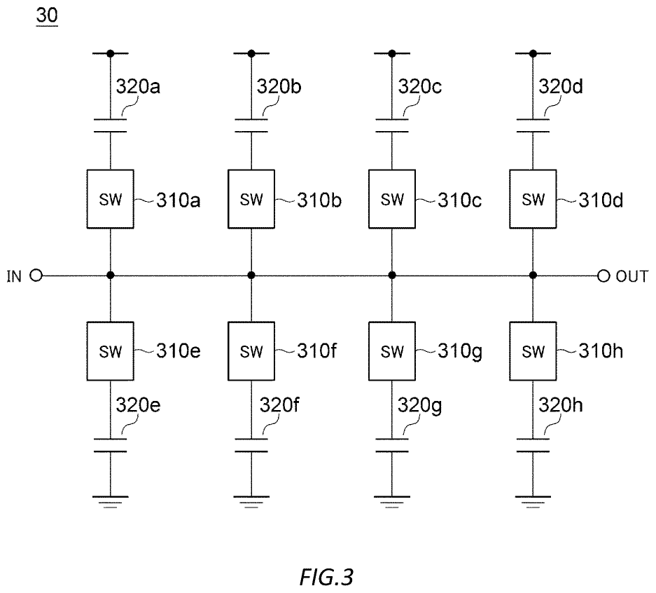

FIG. 3 shows a configuration of a capacitor bank 30 according to the present embodiment. The capacitor bank 30 according to the present embodiment outputs a signal input from an input terminal IN from an output terminal OUT. The capacitor bank 30 allows the capacitance of the capacitor added to the signal line between the input terminal IN and the output terminal OUT to be variable.

The capacitor bank 30 includes a plurality of switch devices 310a to 310h and a plurality of capacitors 320a to 320h. The switch device 310a and the capacitor 320a are connected between the signal line and a power supply potential VCC. Similarly, the switch device 310b and the capacitor 320b, the switch device 310c and the capacitor 320c, and the switch device 310d and the capacitor 320d are connected between the signal line and the power supply potential VCC. The switch device 310e and the capacitor 320e are connected between the signal line and a ground potential GND. Similarly, the switch device 310f and the capacitor 320f, the switch device 310g and the capacitor 320g, and the switch device 310h and the capacitor 320h are connected between the signal line and the ground potential GND. Note that the capacitor bank 30 may include a different number of capacitors and switch devices from the example of this drawing.

Each of the switch devices 310a to 310h may be the switch device 10 shown in FIG. 1 or the switch device 20 shown in FIG. 2. When the switch device 10 shown in FIG. 1 is used as the switch devices 310a to 310d, the second terminal P2 of the switch device 10 is set to the power supply potential VCC side. When the switch device 10 shown in FIG. 1 is used as the switch devices 310e to 310h, the second terminal P2 of the switch device 10 is set to the signal line side.

The capacitors 320a to 320h may have the same capacitance or different capacitances. In addition, each set of the capacitor 320a and the capacitor 320e, the capacitor 320b and the capacitor 320f, the capacitor 320c and the capacitor 320g, and the capacitor 320d and the capacitor 320h may have the same capacitance, and different sets may have different capacitances.

According to the capacitor bank 30 shown in this drawing, it is possible to allow the capacitance added to the signal line to be varied by changing the number or combination of switches to be turned on among the switch devices 310a to 310h. In addition, by using the switch device 10 or the switch device 20 as the switch devices 310a to 310h, the phase-change material switch 100 or the phase-change material switch 200 can be protected even when the amplitude of the signal flowing through the signal line is large.

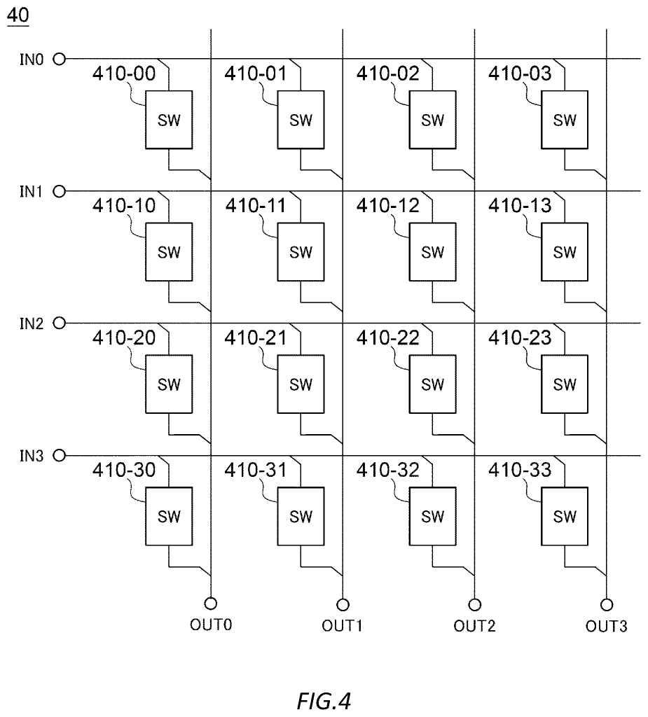

FIG. 4 shows a configuration of a switch matrix 40 according to the present embodiment. The switch matrix 40 according to the present embodiment can switch a connection form between a plurality of input terminals IN0 to IN3 and a plurality of output terminals OUT0 to OUT3.

The switch matrix 40 includes the plurality of input terminals IN0 to IN3, the plurality of output terminals OUT0 to OUT3, and a plurality of switch devices 410-00 to 410-33 (also referred to as a “switch device 410”). Each of the plurality of switch devices 410 is provided between each of the plurality of input terminals IN0 to IN3 and each of the plurality of output terminals OUT0 to OUT3. Each switch device 410 may be the switch device 10 shown in FIG. 1 or the switch device 20 shown in FIG. 2. Note that in the switch matrix 40, at least one of the number of input terminals or the number of output terminals may be different from that in the example of this drawing, and accordingly, the number of switch devices 410 may also be different.

The switch device 410-00 is connected between the output terminal OUT0 and the input terminal IN0, the switch device 410-10 is connected between the output terminal OUT0 and the input terminal IN1, the switch device 410-20 is connected between the output terminal OUT0 and the input terminal IN2, and the switch device 410-30 is connected between the output terminal OUT0 and the input terminal IN3. In the switch matrix 40, the output terminal OUT0 can be electrically connected to the input terminal IN0 by turning on the switch device 410-00 and turning off the other switch devices 410, the output terminal OUT0 can be electrically connected to the input terminal IN1 by turning on the switch device 410-10 and turning off the other switch devices 410, the output terminal OUT0 can be electrically connected to the input terminal IN2 by turning on the switch device 410-20 and turning off the other switch devices 410, and the output terminal OUT0 can be electrically connected to the input terminal IN3 by turning on the switch device 410-30 and turning off the other switch devices 410. Similarly for the other output terminals OUT1 to OUT3, the switch matrix 40 can switch which input terminal the output terminal is electrically connected to by selectively turning on the switch device 410 connected to the output terminal. Note that, although the input terminal and the output terminal are illustrated in the example of this drawing for convenience of description, the switch matrix 40 may exchange electrical signals bidirectionally between the terminals IN0 to IN3 and the terminals OUT0 to OUT3.

While the present invention has been described above by using the embodiments, the technical scope of the present invention is not limited to the scope of the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: switch device; 20: switch device; 30: capacitor bank; 40: switch matrix; 100: phase-change material switch; 110: heater; 120: series switch; 200: phase-change material switch; 210: heater; 220: series switch; 310a to 310h: switch device; 320a to 320h: capacitor; 410-00 to 410-33: switch device.

What is claimed is:

1. A switch device comprising:
a phase-change material switch; and
a first series switch which is connected in series to the phase-change material switch and is normally on.

2. The switch device according to claim 1, wherein
in the phase-change material switch and the first series switch, between a first terminal and a second terminal of the switch device, the phase-change material switch is connected on a side of the first terminal, and the first series switch is connected on a side of the second terminal, and
a control terminal of the first series switch is connected to a terminal of the phase-change material switch on a side of the first terminal.

3. The switch device according to claim 2, further comprising:
a second series switch which is connected in series to the phase-change material switch and is normally on, wherein
between the first terminal and the second terminal of the switch device, the second series switch is connected on a side of the first terminal with respect to the phase-change material switch, and
a control terminal of the second series switch is connected to a terminal of the phase-change material switch on a side of the second terminal.

4. The switch device according to claim 2, wherein the first series switch is turned off in response to a potential difference of the second terminal from the first terminal exceeding a first threshold.

5. The switch device according to claim 3, wherein the first series switch is turned off in response to a potential difference of the second terminal from the first terminal exceeding a first threshold.

6. The switch device according to claim 4, wherein the first threshold is lower than a withstand voltage of the phase-change material switch.

7. The switch device according to claim 5, wherein the first threshold is lower than a withstand voltage of the phase-change material switch.

8. The switch device according to claim 3, wherein the second series switch is turned off in response to a potential difference of the first terminal from the second terminal exceeding a second threshold.

9. The switch device according to claim 4, wherein a withstand voltage of the first series switch is higher than a withstand voltage of the phase-change material switch.

10. The switch device according to claim 5, wherein a withstand voltage of the first series switch is higher than a withstand voltage of the phase-change material switch.

11. The switch device according to claim 6, wherein a withstand voltage of the first series switch is ten times or higher a withstand voltage of the phase-change material switch.
